(19) United States
(12) Patent Application Publication
(10) Pub. No.: US 2025/0183871 A1
(43) Pub. Date: Jun. 5, 2025

(54) ACOUSTIC WAVE DEVICE

(71) Applicant: Murata Manufacturing Co., Ltd., Nagaokakyo-shi (JP)

(72) Inventors: Sho NAGATOMO, Nagaokakyo-shi (JP); Katsuya DAIMON, Nagaokakyo-shi (JP)

(21) Appl. No.: 19/049,110

(22) Filed: Feb. 10, 2025

Related U.S. Application Data
(63) Continuation of application No. PCT/JP2023/030814, filed on Aug. 25, 2023.
(60) Provisional application No. 63/401,255, filed on Aug. 26, 2022.

(51) Int. Cl. H03H 9/13; H03H 9/02; H03H 9/17

(52) U.S. Cl. CPC H03H 9/132; H03H 9/02031; H03H 9/02157; H03H 9/02228; H03H 9/173; H03H 9/175; H03H 9/176

(57) ABSTRACT

An acoustic wave device includes a piezoelectric layer, first and second comb-shaped electrodes respectively including first and second electrode fingers, and a third electrode including third electrode fingers. The first comb-shaped electrode is connected to an input potential. The second comb-shaped electrode is connected to an output potential. The third electrode is connected to a potential different from the first and second comb-shaped electrodes. Each of the third electrode fingers is arranged alongside the first and second electrode fingers. A third busbar interconnects adjacent third electrode fingers. A third electrode finger is between first and second electrode fingers closest to each other. At least one set of electrode fingers selected from the first, second, and third electrode fingers, includes two or more consecutive electrode fingers in the orthogonal-to-electrode-finger direction.

### CROSS REFERENCE TO RELATED APPLICATIONS

This application claims the benefit of priority to Provisional Application No. 63/401,255 filed on Aug. 26, 2022 and is a Continuation Application of PCT Application No. PCT/JP2023/030814 filed on Aug. 25, 2023. The entire contents of each application are hereby incorporated herein by reference.

### BACKGROUND OF THE INVENTION

### 1. Field of the Invention

The present invention relates to acoustic wave devices.

### 2. Description of the Related Art

In the related art, acoustic wave devices are used for a wide range of applications, such as filters of mobile phones. In recent years, acoustic wave devices utilizing bulk waves in thickness shear mode have been proposed, such as one described in U.S. Pat. No. 10,491,192. In the acoustic wave device, a piezoelectric layer is disposed on a support. Electrodes defining an electrode pair are disposed on the piezoelectric layer. The electrodes defining an electrode pair on the piezoelectric layer face each other, and are connected to different potentials. By application of alternating-current voltage between the electrodes, a bulk wave in thickness shear mode is excited.

An example of an acoustic wave device is an acoustic wave resonator, which is used for, for example, a ladder filter. To achieve desirable characteristics for a ladder filter, it is necessary to increase the electrostatic capacitance ratio between a plurality of acoustic wave resonators. In this case, the electrostatic capacitance of a subset of the acoustic wave resonators in the ladder filter needs to be increased.

Increasing the electrostatic capacitance of an acoustic wave resonator necessitates, for example, enlarging the acoustic wave resonator. Consequently, using such an enlarged resonator for a ladder filter tends to result in increased size of the ladder filter. In particular, this leads to an increased size of a ladder filter including an acoustic wave resonator that utilizes bulk waves in thickness shear mode and has low electrostatic capacitance.

The inventors of example embodiments of the present invention have discovered that with a configuration described below for an acoustic wave device makes it possible for a filter device including the acoustic wave device to have a desirable filter waveform without increasing in size. The configuration involves placing, between an electrode connected to an input potential and an electrode connected to an output potential, an electrode connected to a potential different from the input potential and the output potential, such as a reference potential.

Moreover, the inventors of example embodiments of the present invention have also discovered that simply using the above-mentioned configuration may fail to sufficiently increase the pass-band width.

### SUMMARY OF THE INVENTION

Example embodiments of the present invention provide acoustic wave devices that each enable a filter device to have a reduced size and an increased pass-band width.

An acoustic wave device according to an example embodiment of the present invention includes a piezoelectric film, a first comb-shaped electrode, a second comb-shaped electrode, and a third electrode. The piezoelectric film includes a piezoelectric layer. The first comb-shaped electrode is on the piezoelectric layer, and connected to an input potential. The first comb-shaped electrode includes a first busbar, and a plurality of first electrode fingers each connected at one end to the first busbar. The second comb-shaped electrode is on the piezoelectric layer, and connected to an output potential. The second comb-shaped electrode includes a second busbar, and a plurality of second electrode fingers each connected at one end to the second busbar, and being interdigitated with the first electrode fingers. The third electrode is connected to a potential different from the first comb-shaped electrode and the second comb-shaped electrode. The third electrode includes a plurality of third electrode fingers, and a third busbar. Each of the third electrode fingers is on the piezoelectric layer such that, as seen in plan view, the third electrode finger is provided alongside the first electrode finger and the second electrode finger in a direction in which the first electrode finger and the second electrode finger are arranged. The third busbar interconnects adjacent third electrode fingers. The third electrode fingers are located between first and second electrode fingers located nearest to each other as seen in plan view. When a direction orthogonal or substantially orthogonal to a direction in which the first electrode finger, the second electrode finger, and the third electrode finger extend is defined as an orthogonal-to-electrode-finger direction, at least one plurality of electrode fingers selected from the first electrode fingers, the second electrode fingers, and the third electrode fingers include two or more consecutive electrode fingers provided consecutively in the orthogonal-to-electrode-finger direction.

Example embodiments of the present invention provide acoustic wave devices that each enable a filter device to have a reduced size and an increased pass-band width.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic elevational cross-sectional view of an area in a vicinity of first to third electrode fingers according to the first example embodiment of the present invention.

FIG. 4 is a schematic plan view of an acoustic wave device according to Reference Example.

FIG. 5 illustrates bandpass characteristics according to the first example embodiment of the present invention, and bandpass characteristics according to Reference Example.

FIG. 6 is a schematic elevational cross-sectional view, for explaining an odd mode, of an area in a vicinity of first to third electrode fingers according to Reference Example.

FIG. 7 is a schematic elevational cross-sectional view, for explaining an even mode, of an area in a vicinity of first to third electrode fingers according to Reference Example.

FIG. 8 schematically illustrates formation of a pass band in an acoustically coupled filter.

FIG. 9 illustrates a map of fractional bandwidth with respect to the Euler angles (0°, θ, ψ) of LiNbO₃ with d/p set as close to zero as possible.

FIG. 10 is a schematic elevational cross-sectional view of an area in a vicinity of first to third electrode fingers according to a modification of the first example embodiment of the present invention.

FIG. 11 is a schematic plan view of an acoustic wave device according to a second example embodiment of the present invention.

FIG. 12 is a schematic elevational cross-sectional view of an area in a vicinity of first to third electrode fingers according to the second example embodiment of the present invention.

FIG. 13A is a schematic perspective view of an outward appearance of an acoustic wave device that utilizes bulk waves in thickness shear mode, and FIG. 13B is a plan view of an arrangement of electrodes on a piezoelectric layer.

FIG. 14 is a cross-sectional view taken along a line A-A in FIG. 13A.

FIG. 15A is a schematic elevational cross-sectional view of a piezoelectric film of an acoustic wave device, illustrating Lamb waves propagating in the piezoelectric film, and FIG. 15B is a schematic elevational cross-sectional view of a piezoelectric film of an acoustic wave device, illustrating bulk waves in thickness shear mode that propagate in the piezoelectric film.

FIG. 16 illustrates an amplitude directions of bulk waves in thickness shear mode.

FIG. 17 illustrates the resonance characteristics of an acoustic wave device that utilizes bulk waves in thickness shear mode.

FIG. 18 illustrates a relationship between d/p and the fractional bandwidth of a resonator, where p is the center-to-center distance between mutually adjacent electrodes, and d is the thickness of a piezoelectric layer.

FIG. 19 is a plan view of an acoustic wave device that utilizes bulk waves in thickness shear mode.

FIG. 20 illustrates the resonance characteristics of an acoustic wave device according to a reference example in which a spurious response appears.

FIG. 21 illustrates the relationship between fractional bandwidth, and a magnitude of a spurious response, represented by the phase rotation of the spurious impedance normalized to about 180 degrees.

FIG. 22 illustrates the relationship between d/2p, and a metallization ratio MR.

FIG. 23 illustrates a map of fractional bandwidth with respect to the Euler Angles (0°, θ, ψ) of LiNbO₃ with d/p set as close to zero as possible.

FIG. 24 is an elevational cross-sectional view of an acoustic wave device including an acoustic multilayer film.

FIG. 25 is a partly cutaway perspective view of an acoustic wave device that utilizes Lamb waves.

### DETAILED DESCRIPTION OF THE EXAMPLE EMBODIMENTS

Example embodiments of the present invention will now be described with reference to the drawings to clearly explain the present invention.

Various example embodiments described herein are for illustrative purposes only, and components or features described with respect to different example embodiments may be partially substituted for or combined with each other.

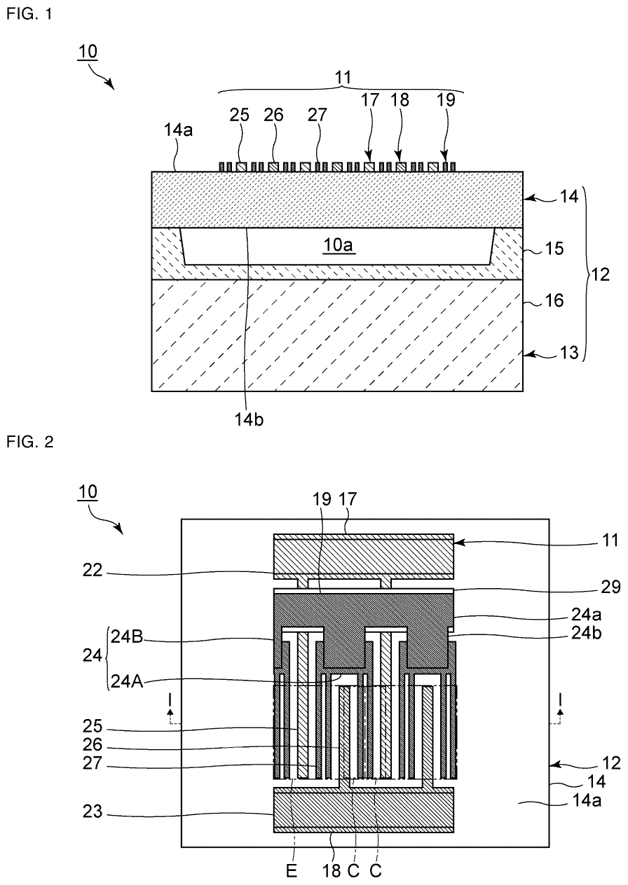

FIG. 1 is a schematic elevational cross-sectional view of an acoustic wave device according to a first example embodiment of the present invention. FIG. 2 is a schematic plan view of the acoustic wave device according to the first example embodiment. FIG. 1 is a schematic cross-sectional view taken along a line I-I in FIG. 2. In FIG. 2, individual electrodes are depicted in hatching. In schematic plan views other than FIG. 2, the electrodes are likewise depicted in hatching in some cases.

An acoustic wave device 10 illustrated in FIG. 1 is capable of utilizing a thickness shear mode. The acoustic wave device 10 is an acoustically coupled filter. The configuration of the acoustic wave device 10 is now described below.

The acoustic wave device 10 includes a piezoelectric substrate 12, and a functional electrode 11. The piezoelectric substrate 12 has piezoelectricity. Specifically, the piezoelectric substrate 12 includes a support 13, and a piezoelectric layer 14 defining and functioning as a piezoelectric film. The piezoelectric layer 14 is a layer including a piezoelectric body. The term piezoelectric film as used herein refers to a film having piezoelectricity, and does not necessarily refer to a film made of a piezoelectric body. According to the first example embodiment, however, the piezoelectric film is a single piezoelectric layer 14, and made of a piezoelectric body. According to example embodiments of the present invention, the piezoelectric film may be a multilayer film including the piezoelectric layer 14. According to the first example embodiment, the support 13 includes a support substrate 16, and an insulating layer 15. The insulating layer 15 is disposed on the support substrate 16. The piezoelectric layer 14 is disposed on the insulating layer 15. The configuration described above is not intended to be limiting. In another configuration, the support 13 may include only the support substrate 16. The support 13 does not necessarily have to be provided.

The piezoelectric layer 14 includes a first major surface 14a, and a second major surface 14b. The first major surface 14a and the second major surface 14b are positioned opposite from each other. Of the first major surface 14a and the second major surface 14b, the second major surface 14b is located near the support 13. According to the first example embodiment, the piezoelectric layer 14 is made of, for example, lithium niobate. Specifically, the piezoelectric layer 14 is made of, for example, Z-cut LiNbO₃. However, for example, the piezoelectric layer 14 may be made of rotated Y-cut lithium niobate. Alternatively, the piezoelectric layer 14 may be made of lithium tantalate such as LiTaO₃, for example. When it is stated herein that a certain component or member is made of a certain material, this includes cases where the component or member includes a trace amount of impurity that does not significantly deteriorate the electrical characteristics of the acoustic wave device.

The functional electrode 11 is disposed on the first major surface 14a of the piezoelectric layer 14. As illustrated in FIG. 2, the functional electrode 11 includes a pair of comb-shaped electrodes, and a third electrode 19. The pair of comb-shaped electrodes specifically include a first comb-shaped electrode 17, and a second comb-shaped electrode 18. The first comb-shaped electrode 17 is connected to an input potential. The second comb-shaped electrode 18 is connected to an output potential. According to the first example embodiment, the third electrode 19 is connected to a reference potential. The third electrode 19 does not necessarily have to be connected to a reference potential. It may suffice that the third electrode 19 is connected to a potential different from the first comb-shaped electrode 17 and the second comb-shaped electrode 18. It is preferable, however, that the third electrode 19 is connected to a reference potential.

The first comb-shaped electrode 17 and the second comb-shaped electrode 18 are disposed on the first major surface 14a of the piezoelectric layer 14. The first comb-shaped electrode 17 includes a first busbar 22, and a plurality of first electrode fingers 25. Each of the first electrode fingers 25 is connected at one end to the first busbar 22. The second comb-shaped electrode 18 includes a second busbar 23, and a plurality of second electrode fingers 26. Each of the second electrode fingers 26 is connected at one end to the second busbar 23.

The first busbar 22 and the second busbar 23 face each other. The first electrode fingers 25 and the second electrode fingers 26 are interdigitated with each other. In a direction orthogonal or substantially orthogonal to the direction in which the first electrode finger 25 and the second electrode finger 26 extend, the first electrode finger 25 and the second electrode finger 26 are arranged alternately.

The third electrode 19 includes a third busbar 24, which defines and functions as a connection electrode, and a plurality of third electrode fingers 27. The third electrode fingers 27 are disposed on the first major surface 14a of the piezoelectric layer 14. The third electrode fingers 27 are electrically connected to each other by the third busbar 24.

In plan view, each of the third electrode fingers 27 is disposed alongside the first electrode finger 25 and the second electrode finger 26. The first electrode finger 25, the second electrode finger 26, and the third electrode finger 27 are thus arranged in one direction. The third electrode fingers 27 extend in parallel to the first electrode fingers 25 and the second electrode fingers 26.

As used herein, the expression “in plan view” refers to viewing in the direction in which the support 13 and the piezoelectric film are stacked, from a position corresponding to the upper side in FIG. 1. In FIG. 1, for example, of the support substrate 16 and the piezoelectric layer 14, the piezoelectric layer 14 is located at the upper side. Further, as used herein, the expression “in plan view” is to be considered synonymous with viewing in a major surface opposing direction. The major surface opposing direction refers to a direction in which the first major surface 14a and the second major surface 14b of the piezoelectric layer 14 are positioned opposite from each other. More specifically, the major surface opposing direction is, for example, the direction of the normal to the first major surface 14a.

In the following description, a direction in which the first electrode finger 25, the second electrode finger 26, and the third electrode finger 27 extend is defined as electrode-finger extending direction, and a direction orthogonal or substantially orthogonal to the electrode-finger extending direction is defined as orthogonal-to-electrode-finger direction. When a direction in which the first electrode finger 25, the second electrode finger 26, and the third electrode finger 27 are arranged is defined as electrode-finger arrangement direction, the electrode-finger arrangement direction is parallel or substantially parallel to the orthogonal-to-electrode-finger direction. The first electrode finger 25, the second electrode finger 26, and the third electrode finger 27 are herein sometimes collectively referred to simply as electrode finger or electrode fingers.

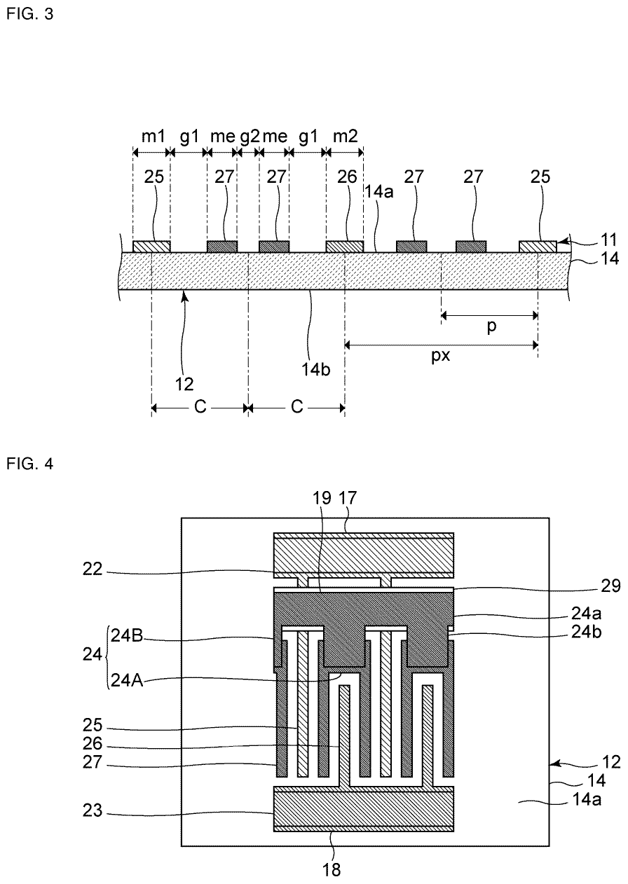

FIG. 3 is a schematic elevational cross-sectional view of an area in the vicinity of first to third electrode fingers according to the first example embodiment.

Each two third electrode fingers 27 are disposed between the first electrode finger 25 and the second electrode finger 26. According to the first example embodiment, the third electrode fingers 27 are consecutive electrode fingers. Consecutive electrode fingers refer to two or more electrode fingers that are disposed consecutively in the orthogonal-to-electrode-finger direction, and that are connected to the same potential. Hereinafter, two or more consecutive electrode fingers that are disposed consecutively in the orthogonal-to-electrode-finger direction will be sometimes referred to as a set of consecutive electrode fingers.

With a set of consecutive electrode fingers regarded as a single electrode finger, the electrode fingers are arranged in the following sequence that define one period when starting with the first electrode finger 25: the first electrode finger 25, the third electrode finger 27, the second electrode finger 26, and the third electrode finger 27. Therefore, the electrode fingers are arranged in the sequence of the first electrode finger 25, the third electrode finger 27, the second electrode finger 26, the third electrode finger 27, the first electrode finger 25, the third electrode finger 27, the second electrode finger 26, and so on. With the input potential represented as IN, the output potential as OUT, and the reference potential as GND, the sequence of the electrode fingers is represented as the following sequence of the potentials to which the electrode fingers are connected: IN, GND, OUT, GND, IN, GND, OUT, and so on.

According to example embodiments of the present invention, at least one plurality of electrode fingers selected from the first electrode fingers 25, the second electrode fingers 26, and the third electrode fingers 27 may include consecutive electrode fingers. In one example, the first electrode fingers 25 may include consecutive electrode fingers. In this case, two or more first electrode fingers 25 may be disposed consecutively between the adjacent third electrode fingers 27.

In another example, the second electrode fingers 26 may include consecutive electrode fingers. In this case, two or more second electrode fingers 26 may be disposed consecutively between the adjacent third electrode fingers 27. In each of the above-described cases as well, the third electrode finger 27 may be disposed between the first electrode finger 25 and the second electrode finger 26 that are located nearest each other.

According to the first example embodiment, in a region where the electrode fingers are provided, the electrode finger located at each end portion of the region in the orthogonal-to-electrode-finger direction is the third electrode finger 27. Alternatively, in the region described above, an electrode finger located at an end portion of the region in the orthogonal-to-electrode-finger direction may be any one of the first electrode finger 25, the second electrode finger 26, or the third electrode finger 27.

As illustrated in FIG. 2, the third busbar 24, which defines and functions as a connection electrode of the third electrode 19, electrically connects the third electrode fingers 27 to each other. Specifically, the third busbar 24 is located in the region between the first busbar 22, and the tip of each of the second electrode fingers 26. The first electrode fingers 25 are also located in this region. However, the third busbar 24, and each of the first electrode fingers 25 are electrically insulated from each other by an insulating film 29.

More specifically, the third busbar 24 includes a plurality of first connection electrodes 24A, and a single second connection electrode 24B. Each of the first connection electrodes 24A interconnects the respective tips of four consecutive third electrode fingers 27 in the orthogonal-to-electrode-finger direction. In other words, each of the first connection electrode 24A interconnects the respective tips of two sets of consecutive electrode fingers. The first connection electrodes 24A are connected to each other by the second connection electrode 24B. The insulating film 29 is disposed between the second connection electrode 24B, and each of the first electrode fingers 25.

More specifically, the insulating film 29 is disposed over the first major surface 14a of the piezoelectric layer 14 so as to cover a portion of the first electrode fingers 25. The insulating film 29 is disposed in the region between the first busbar 22, and the tip of each of the second electrode fingers 26. The insulating film 29 is band-shaped.

The insulating film 29 does not extend to the area over the first connection electrodes 24A of the third electrode 19. The second connection electrode 24B is disposed over the insulating film 29 and over the first connection electrodes 24A. Specifically, the second connection electrode 24B has a bar portion 24a, and a plurality of projections 24b. Each projection 24b extends from the bar portion 24a toward the corresponding first connection electrode 24A. Each projection 24b is connected to the corresponding first connection electrode 24A. As a result, the third electrode fingers 27 are electrically connected to each other by the first connection electrode 24A and the second connection electrode 24B.

According to the first example embodiment, the third busbar 24 is located in the region between the first busbar 22, and the tip of each of the second electrode fingers 26. Accordingly, the tip of each of the second electrode fingers 26 faces the third busbar 24 in the electrode-finger extending direction with a gap therebetween. The tip of each of the first electrode fingers 25 faces the second busbar 23 in the electrode-finger extending direction with a gap therebetween.

The third busbar 24 may be located in the region between the second busbar 23, and the tip of each of the first electrode fingers 25. In this case, the tip of each of the first electrode fingers 25 faces the third busbar 24 with a gap therebetween. Further, in this case, the tip of each of the second electrode fingers 26 faces the first busbar 22 with a gap therebetween.

The acoustic wave device 10 is an acoustic wave resonator capable of utilizing bulk waves in thickness shear mode. As illustrated in FIG. 2, the acoustic wave device 10 includes a plurality of excitation regions C. In the excitation regions C, bulk waves in thickness shear mode, or acoustic waves in other modes are excited. FIG. 2 depicts only two of the excitation regions C.

One edge of the excitation region C coincides with the center in the orthogonal-to-electrode-finger direction of one of the first, second, and third electrode fingers 25, 26, and 27 that is adjacent to a set of consecutive electrode fingers, and that is connected to a potential different from the set of consecutive electrode fingers. The other edge coincides with the center in the orthogonal-to-electrode-finger direction of the set of consecutive electrode fingers. The distance between opposite edges of the excitation region C is denoted p.

According to the first example embodiment, some of the excitation regions C are regions each located between the center in the orthogonal-to-electrode-finger direction of the first electrode finger 25, and the center in the orthogonal-to-electrode-finger direction of a set of consecutive electrode fingers adjacent to the first electrode finger 25. Each of the remaining excitation regions C is a region located between the center in the orthogonal-to-electrode-finger direction of the second electrode finger 26, and the center in the orthogonal-to-electrode-finger direction of a set of consecutive electrode fingers adjacent to the second electrode finger 26. The excitation regions C are arranged in the orthogonal-to-electrode-finger direction.

In the acoustic wave device 10, the portion of the functional electrode 11 excluding the third electrode 19 has the same or similar configuration to an interdigital transducer (IDT) electrode. A region where, as seen in the orthogonal-to-electrode-finger direction, the first electrode finger 25 and the second electrode finger 26 that are adjacent to each other overlap is an intersecting region E. However, the intersecting region E can also be said to be a region in which, as seen in the orthogonal-to-electrode-finger direction, the first electrode finger 25 and the third electrode finger 27 that are adjacent to each other overlap, or the second electrode finger 26 and the third electrode finger 27 that are adjacent to each other overlap. The intersecting region E includes a plurality of excitation regions C. The intersecting region E and each excitation region C are regions on the piezoelectric layer 14 that are defined based on the configuration of the functional electrode 11.

Hereinafter, as illustrated in FIG. 3, of two different electrode fingers each connected to a potential different from consecutive electrode fingers, one electrode finger has a width m1, the other electrode finger has a width m2, and each of the consecutive electrode fingers has a width me. According to the first example embodiment, the first electrode finger 25 has the width m1. The second electrode finger 26 has the width m2. The third electrode finger 27 has the width me. The width of an electrode finger refers to the dimension of the electrode finger in the orthogonal-to-electrode-finger direction.

The distance between one of consecutive electrode fingers, and an electrode finger connected to a potential different from the one of consecutive electrode fingers is denoted g1. The distance between adjacent consecutive electrode fingers is denoted g2. The distance g1 and the distance g2 each represent the distance between an edge of an electrode finger and an edge of an electrode finger. The expression “edge of an electrode finger” as used herein refers to an edge of the electrode finger in the orthogonal-to-electrode-finger direction as seen in plan view.

According to the first example embodiment, the distance g1 represents the distance between an edge of the first electrode finger 25 near the third electrode finger 27, and an edge of the third electrode finger 27 near the first electrode finger 25. Similarly, the distance g1 represents the distance between an edge of the second electrode finger 26 near the third electrode finger 27, and an edge of the third electrode finger 27 near the second electrode finger 26. The distance g2 represents the distance between respective edges of mutually adjacent third electrode fingers 27 that are near each other.

Of two kinds of electrode fingers that are connected to a potential different from consecutive electrode fingers, and that are connected to potentials different from each other, the electrode fingers that are located nearest to each other have a center-to-center distance px between each other. According to the first example embodiment, the first electrode finger 25 and the second electrode finger 26 that are located nearest to each other have the center-to-center distance px between each other.

The first electrode finger 25, the second electrode finger 26, and the third electrode finger 27 are each made of Al, for example. The material of each of the first electrode finger 25, the second electrode finger 26, and the third electrode finger 27 is not limited to Al. Alternatively, the first electrode finger 25, the second electrode finger 26, and the third electrode finger 27 may each include, for example, a multilayer metal film.

The first example embodiment has the following features. (1) The third electrode finger 27 is disposed between the first electrode finger 25 and the second electrode finger 26 that are located nearest to each other as seen in plan view. (2) At least one plurality of electrode fingers selected from the first electrode fingers 25, the second electrode fingers 26, and the third electrode fingers 27 include consecutive electrode fingers. As a result, when the acoustic wave device 10 is used for a filter device, the resulting filter device can have a reduced size, and an increased pass-band width. This is explained below through comparison between the first example embodiment and Reference Example.

Reference Example differs from the first example embodiment in that, as illustrated in FIG. 4, the functional electrode includes no consecutive electrode fingers. An acoustic wave device according to Reference Example is an acoustically coupled filter. The bandpass characteristics according to the first example embodiment, and the bandpass characteristics according to Reference Example are compared with each other. The acoustic wave device 10 configured in accordance with the first example embodiment has design parameters described below. In this case, the thickness of the piezoelectric film is denoted d. According to the first example embodiment, the thickness d refers to the thickness of the piezoelectric layer 14.
Piezoelectric layer: material . . . Z-cut LiNbO₃, thickness d . . . about 400 nm
Material of first to third electrode fingers: Al
Thickness of first to third electrode fingers . . . about 400 nm
Respective widths of first to third electrode fingers: width m1 of first electrode finger . . . about 420 nm, width m2 of second electrode finger . . . about 420 nm, width me of third electrode finger . . . about 350 nm
Distance g1 between first electrode finger and third electrode finger, and distance g1 between second electrode finger and third electrode finger: equal or substantially equal.
Distance g2 between mutually adjacent third electrode fingers: about 140 nm
Center-to-center distance px between first electrode finger and second electrode finger: about 2.8 μm
Design parameters according to Reference Example are the same as those according to the first example embodiment, except that the distance g2 is zero.

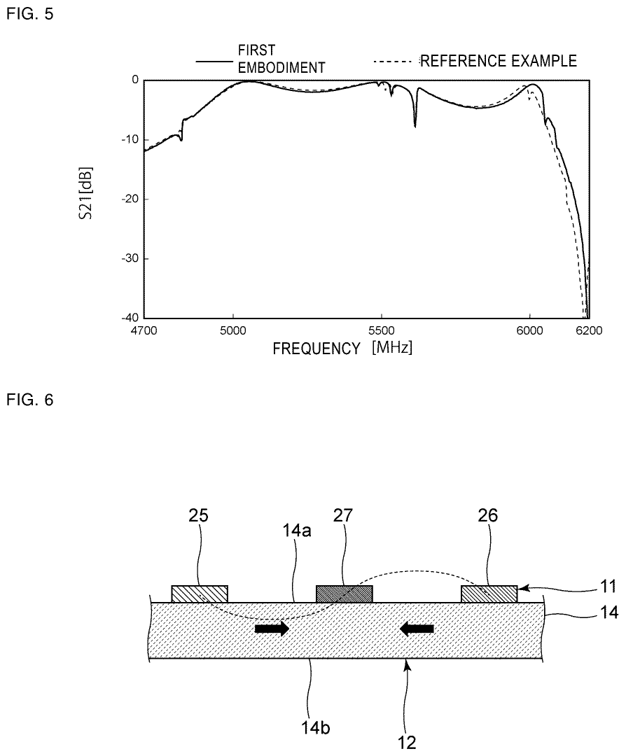

FIG. 5 illustrates respective bandpass characteristics according to the first example embodiment and Reference Example. FIG. 5 illustrates S21 bandpass characteristics.

As illustrated in FIG. 5, according to each of the first example embodiment and Reference Example, a pass band is obtained. It can be appreciated that according to the first example embodiment, the width of the pass band can be increased relative to the width of the pass band according to Reference Example.

The acoustic wave device 10 according to the first example embodiment is, for example, an acoustically coupled filter. As illustrated in FIG. 2, the acoustic wave device 10 includes the excitation region C that is located between the following positions: the center in the orthogonal-to-electrode-finger direction of the first electrode finger 25; and the center in the orthogonal-to-electrode-finger direction of a set of consecutive electrode fingers adjacent to the first electrode finger 25. The acoustic wave device 10 includes the excitation region C that is located between the following positions: the center in the orthogonal-to-electrode-finger direction of the second electrode finger 26; and the center in the orthogonal-to-electrode-finger direction of a set of consecutive electrode fingers adjacent to the second electrode finger 26. A plurality of modes of acoustic waves are excited in these excitation regions C.

The acoustic wave device according to Reference Example also includes a plurality of excitation regions. The excitation regions according to Reference Example include a region located between the respective centers of the first electrode finger 25 and the third electrode finger 27 that are adjacent to each other, and a region located between the respective centers of the second electrode finger 26 and the third electrode finger 27 that are adjacent to each other.

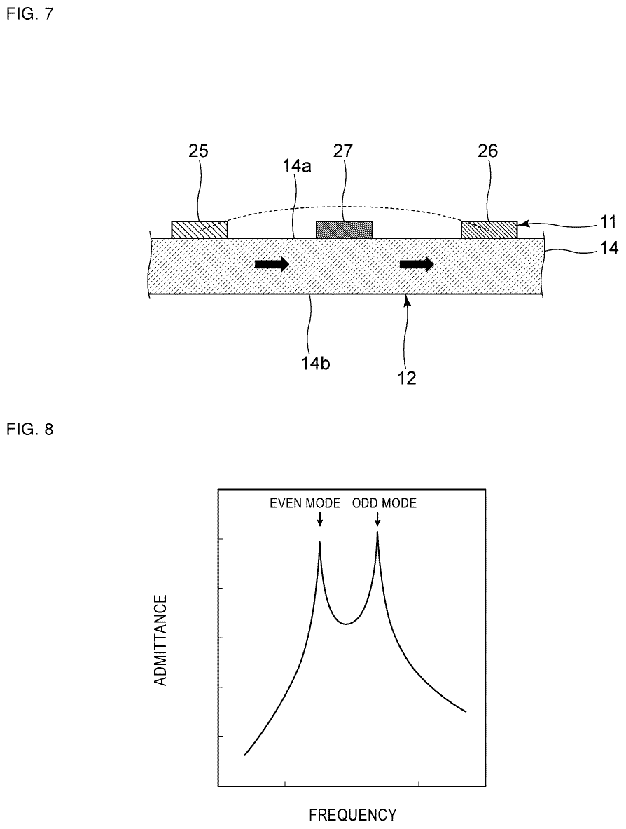

FIG. 6 is a schematic elevational cross-sectional view, for explaining an odd mode, of an area in the vicinity of first to third electrode fingers according to Reference Example. FIG. 7 is a schematic elevational cross-sectional view, for explaining an even mode, of an area in the vicinity of first to third electrode fingers according to Reference Example. FIG. 8 schematically illustrates formation of a pass band in an acoustically coupled filter. Arrows in FIGS. 6 and 7 each represent the direction of an electric field.

In an acoustically coupled filter, the odd mode illustrated in FIG. 6, and the even mode illustrated in FIG. 7 occur. The odd mode is a mode in which electrical conditions are in phase. FIG. 6 depicts a region corresponding to one wavelength of the odd mode. One wavelength of the odd mode refers to the center-to-center distance px between the first electrode finger 25 and the second electrode finger 26 that are adjacent to each other. When the wavelength of the odd mode is λo, λo=px. Therefore, the half-wavelength (½)λo of the odd mode is 0.5 px.

The even mode is a mode in which electrical conditions are in anti-phase. FIG. 7 depicts a region corresponding to the half-wavelength of the even mode. The half-wavelength of the even mode refers to the center-to-center distance px between the first electrode finger 25 and the second electrode finger 26 that are adjacent to each other. When the wavelength of the even mode is λe, (½)λe=px. The wavelength λe of the even mode is twice the wavelength λo of the odd mode.

As illustrated in FIG. 8, in an acoustically coupled filter, a pass band is defined by the even mode and the odd mode. The even mode defines the lower edge of the pass band. The odd mode defines the upper edge of the pass band.

The modes, the pass band, and other details illustrated in FIGS. 6 to 8 are based on the configuration of the acoustically coupled filter according to Reference Example. According to the first example embodiment as well, as with Reference Example, the pass band is defined by the odd mode and the even mode. A suitable filter waveform can be thus obtained even with a single acoustic wave device 10. For a case where the acoustic wave device 10 is to be used as an acoustic wave resonator for a filter device, a suitable filter waveform can be obtained even if the filter device includes a single or only a few acoustic wave resonators. Therefore, the filter device can be reduced in size.

Moreover, according to the first example embodiment, the functional electrode 11 includes consecutive electrode fingers. This configuration allows for mode control, and increased pass-band width.

Preferably, as with the first example embodiment, the third electrode fingers 27 are consecutive electrode fingers. This configuration makes it possible to achieve suitable filter characteristics.

More specifically, according to Reference Example, in the region corresponding to the half-wavelength of the even mode, mass is added by the third electrode finger 27 as illustrated in FIG. 7. The same is true for the first example embodiment. However, according to the first example embodiment, each of consecutive electrode fingers is the third electrode finger 27. By adjusting, for example, the positioning and width of the third electrode fingers 27 defining a set of consecutive electrode fingers, the addition of mass can be easily adjusted in the region corresponding to the half-wavelength of the even mode. This makes it possible to adjust the frequency of the even mode, and consequently achieve suitable filter characteristics.

Preferably, as with the first example embodiment illustrated in FIG. 3, the distance g1 and the distance g2 have the relationship g2≤g1. This makes it possible to reduce the influence that the presence of consecutive electrode fingers has on the odd mode. This helps to reduce degradation of filter characteristics.

The configuration according to the first example embodiment will now be described in more detail.

As illustrated in FIG. 1, the support 13 includes the support substrate 16, and the insulating layer 15. The piezoelectric substrate 12 is a stack including the support substrate 16, the insulating layer 15, and the piezoelectric layer 14. That is, the piezoelectric layer 14 and the support 13 overlap each other as seen in a direction in which the first major surface 14a and the second major surface 14b of the piezoelectric layer 14 are positioned opposite from each other.

Non-limiting examples of the material of the support substrate 16 include semiconductors such as silicon, and ceramics such as aluminum oxide. An example of the material of the insulating layer 15 is any suitable dielectric such as silicon oxide or tantalum oxide.

The insulating layer 15 includes a recess. The piezoelectric layer 14 defining and functioning as a piezoelectric film is disposed on the insulating layer 15 so as to close the recess. A hollow is thus provided. The hollow defines and functions as a cavity 10a. According to the first example embodiment, the support 13 and the piezoelectric film are positioned such that a portion of the support 13 and a portion of the piezoelectric film face each other across the cavity 10a. The recess in the support 13, however, may be provided so as to extend over the insulating layer 15 and the support substrate 16. Alternatively, the recess may be provided only in the support substrate 16, and closed by the insulating layer 15. The recess may be provided in, for example, the piezoelectric layer 14. The cavity 10a may be a through-hole provided in the support 13.

The cavity 10a corresponds to an acoustic reflection portion. The presence of the acoustic reflection portion allows the energy of an acoustic wave to be effectively confined toward the piezoelectric layer 14. It may suffice that the acoustic reflection portion is provided in a location at the support 13 where, as seen in plan view, the acoustic reflection portion overlaps at least a portion of the functional electrode 11. More specifically, it may suffice that, as seen in plan view, the first electrode finger 25, the second electrode finger 26, and the third electrode finger 27 each at least partially overlap the acoustic reflection portion. Preferably, as seen in plan view, a plurality of excitation regions C overlap the acoustic reflection portion.

The acoustic reflection portion may be an acoustic reflection film that will be described later, such as an acoustic multilayer film. For example, the acoustic reflection film may be provided on the surface of the support.

As previously described, one edge of the excitation region C coincides with the center in the orthogonal-to-electrode-finger direction of one of the first, second, and third electrode fingers 25, 26, and 27 that is adjacent to a set of consecutive electrode fingers, and that is connected to a potential different from the set of consecutive electrode fingers. The other edge coincides with the center in the orthogonal-to-electrode-finger direction of the set of consecutive electrode fingers. The distance between opposite edges of the excitation region C is p. In this case, when the piezoelectric film has a thickness d, d/p is, for example, preferably less than or equal to about 0.5, or more preferably less than or equal to about 0.24. This allows bulk waves in thickness shear mode to be excited in a suitable manner. According to the first example embodiment, the thickness d refers to the thickness of the piezoelectric layer 14.

The acoustic wave devices according to example embodiments of the present invention do not necessarily have to be capable of utilizing bulk waves in thickness shear mode. For example, an acoustic wave device according to an example embodiment of the present invention may be capable of utilizing plate waves. In this case, each excitation region is the intersecting region E illustrated in FIG. 2.

As described above, according to the first example embodiment, the piezoelectric layer 14 is made of, for example, Z-cut LiNbO₃. However, the piezoelectric layer 14 may be made of, for example, rotated Y-cut lithium niobate. In this case, the fractional bandwidth of the acoustic wave device 10 depends on the Euler Angles (φ, θ, ψ) of lithium niobate used in the piezoelectric layer 14. The fractional bandwidth is represented by (|fa−fr|/fr)×100[%], where fr is the resonant frequency, and fa is the anti-resonant frequency.

Now, for a case where d/p is set as close to zero as possible, the relationship between the fractional bandwidth of the acoustic wave device 10, and the Euler Angles (φ, θ, ψ) of the piezoelectric layer 14 is derived. In this case, p of the Euler Angles is set at 0°.

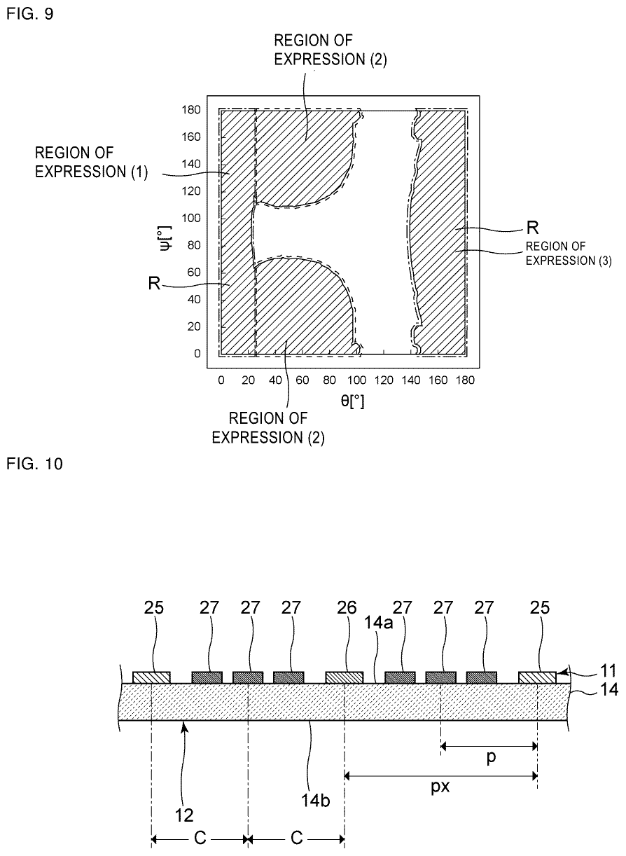

FIG. 9 illustrates a map of fractional bandwidth with respect to the Euler angles (0°, θ, ψ) of LiNbO₃ with d/p set as close to zero as possible.

Hatched regions R in FIG. 9 represent regions where, for example, a fractional bandwidth of at least greater than or equal to about 2% is obtained. The ranges of individual regions R are approximated by Expressions (1), (2), and (3) below. For a case where p of the Euler Angles (φ, θ, ψ) is within the range of about 0°±10°, the relationship between each of θ and ψ, and fractional bandwidth is the same or substantially the same as the relationship illustrated in FIG. 9. For a case where the piezoelectric layer 14 is, for example, a lithium tantalate layer as well, the relationship between each of θ and ψ of the Euler Angles (0°±10°, θ, ψ), and fractional bandwidth is the same or substantially the same as the relationship illustrated in FIG. 9.

(0°±10°,0° to 25°, any ψ) (1)

(0°±10°,25° to 100°,0° to 75°[(1−(θ−50)²/2500)]^{1/2} or 180°−75°[(1−(θ−50)²/2500)]^{1/2} to 180°) (2)

(0°±10°,180°−40°[(1−(ψ−90)²/8100)]^{1/2} to 180°, any ψ) (3)

The Euler angles are preferably in the range represented by Expression (1), (2), or (3). As a result, a sufficiently large fractional bandwidth can be achieved. This allows the acoustic wave device 10 to be suitably used for a filter device.

According to the first example embodiment, each two third electrode fingers 27 defining consecutive electrode fingers are disposed consecutively in the orthogonal-to-electrode-finger direction. The number of consecutive electrode fingers to be disposed consecutively in the orthogonal-to-electrode-finger direction is not limited to two. For example, according to a modification of the first example embodiment illustrated in FIG. 10, each three third electrode fingers 27 defining consecutive electrode fingers are disposed consecutively in the orthogonal-to-electrode-finger direction. In this case, three third electrode fingers 27 define a set of consecutive electrode fingers. According to the present modification as well, as with the first example embodiment, when the acoustic wave device is used for a filter device, the resulting filter device can have a reduced size, and an increased pass-band width.

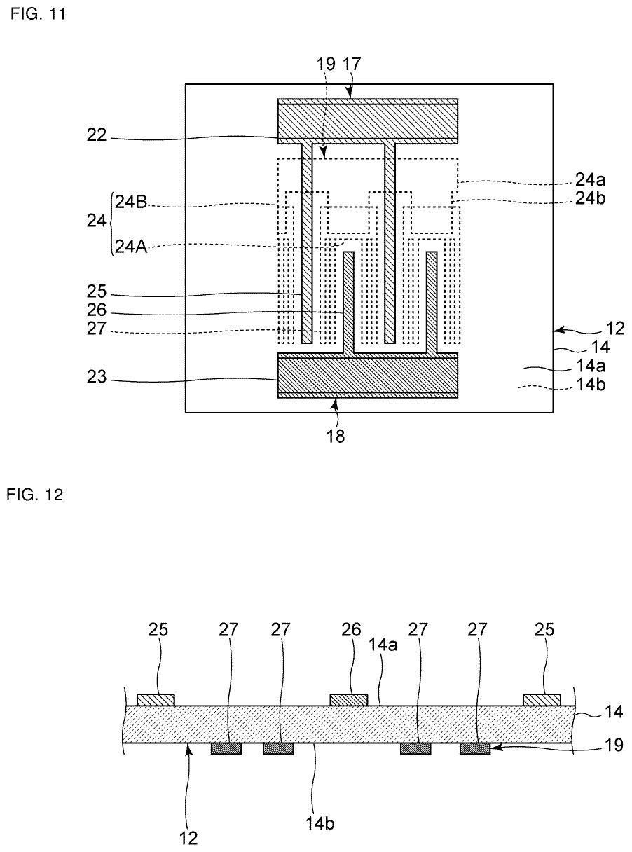

FIG. 11 is a schematic plan view of an acoustic wave device according to a second example embodiment of the present invention. FIG. 12 is a schematic elevational cross-sectional view of an area in the vicinity of first to third electrode fingers according to the second example embodiment.

As illustrated in FIGS. 11 and 12, the second example embodiment differs from the first example embodiment in that the third electrode 19 is disposed on the second major surface 14b of the piezoelectric layer 14. The acoustic wave device according to the second example embodiment otherwise has the same or substantially the same configuration to the acoustic wave device 10 according to the first example embodiment.

The positioning of the third electrode 19 as seen in plan view is the same or substantially the same as that according to the first example embodiment. Therefore, as seen in plan view, the third electrode fingers 27 are disposed on the second major surface 14b of the piezoelectric layer 14 such that, in a direction in which the first electrode finger 25 and the second electrode finger 26 are arranged, each of the third electrode fingers 27 is disposed alongside the first electrode finger 25 and the second electrode finger 26. In plan view, the third electrode fingers 27 defining consecutive electrode fingers are located between the first electrode finger 25 and the second electrode finger 26.

According to the second example embodiment, as with the first example embodiment, when the acoustic wave device is used for a filter device, the resulting filter device can have a reduced size, and an increased pass-band width.

The thickness shear mode is described below in detail with reference to an example in which the functional electrode is an IDT electrode. The IDT electrode includes no third electrode. An “electrode” in the IDT electrode described later corresponds to an electrode finger. A support in the example described below corresponds to the support substrate. In the following description, a reference potential is sometimes referred to as ground potential.

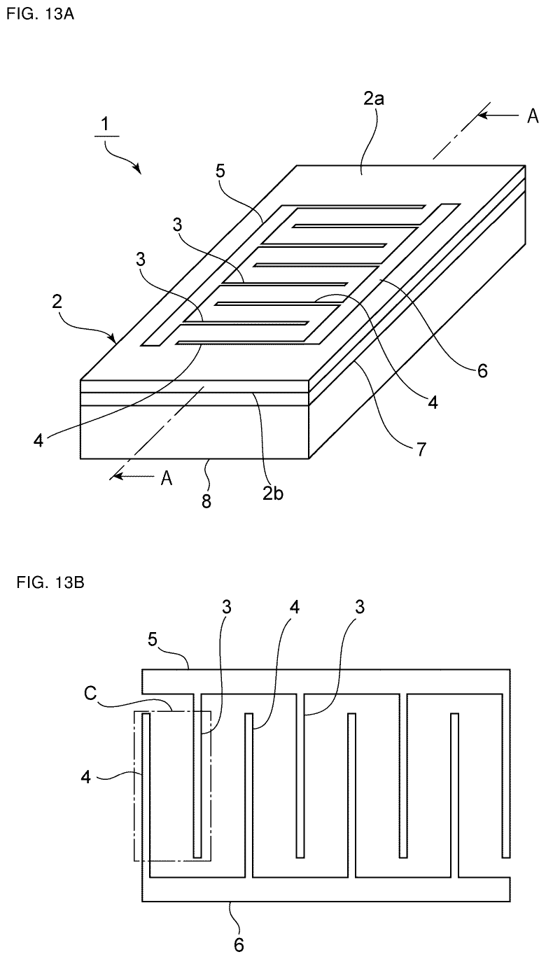

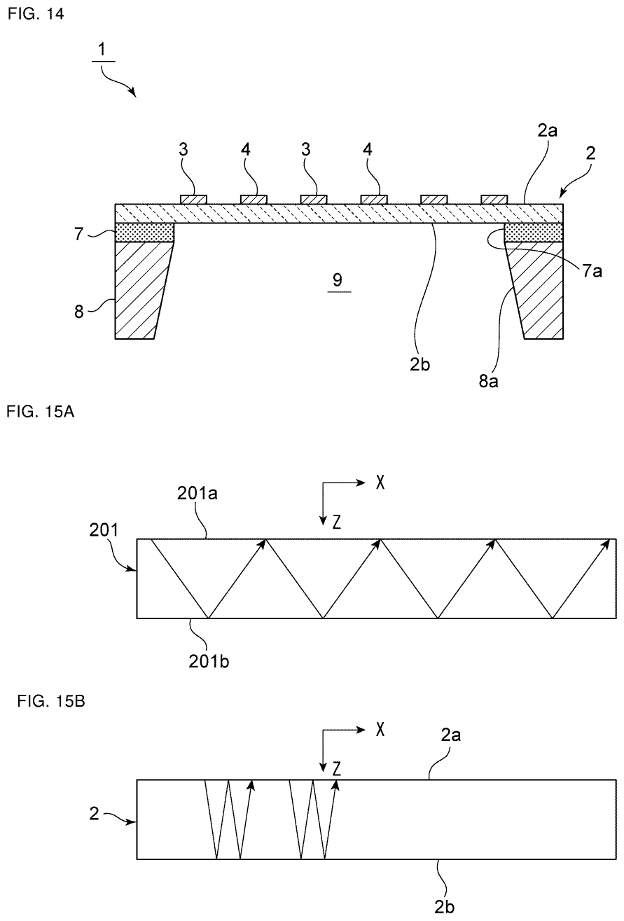

FIG. 13A is a schematic perspective view of the outward appearance of an acoustic wave device that utilizes bulk waves in thickness shear mode. FIG. 13B is a plan view of an arrangement of electrodes on a piezoelectric layer. FIG. 14 is a cross-sectional view taken along a line A-A in FIG. 13A.

An acoustic wave device 1 includes a piezoelectric layer 2 made of, for example, LiNbO₃. The piezoelectric layer 2 may be made of, for example, LiTaO₃. Although the cut-angle of the LiNbO₃ or LiTaO₃ used is a Z-cut, the cut-angle may be a rotated Y-cut or X-cut. Although the thickness of the piezoelectric layer 2 is not particularly limited, from the viewpoint of effectively exciting a thickness shear mode, the piezoelectric layer 2 preferably has a thickness of, for example, greater than or equal to about 40 nm and less than or equal to about 1000 nm, or more preferably greater than or equal to about 50 nm and less than or equal to about 1000 nm. The piezoelectric layer 2 includes a first major surface 2a and a second major surface 2b that are positioned opposite from each other. An electrode 3 and an electrode 4 are disposed on the first major surface 2a. The electrode 3 is an example of a “first electrode”, and the electrode 4 is an example of a “second electrode.” In FIGS. 13A and 13B, a plurality of electrodes 3 are connected to a first busbar 5. A plurality of electrodes 4 are connected to a second busbar 6. The electrodes 3 and the electrodes 4 are interdigitated with each other. Each of the electrode 3 and the electrode 4 has a rectangular or substantially rectangular shape, and has a longitudinal direction. In a direction orthogonal or substantially orthogonal to the longitudinal direction, the electrode 3, and the electrode 4 adjacent to the electrode 3 face each other. The longitudinal direction of the electrodes 3 and 4, and the direction orthogonal or substantially orthogonal to the longitudinal direction of the electrodes 3 and 4 are each a direction that crosses the thickness direction of the piezoelectric layer 2. It can thus be said that the electrode 3, and the electrode 4 adjacent to the electrode 3 face each other in the direction that crosses the thickness direction of the piezoelectric layer 2. The longitudinal direction of the electrodes 3 and 4 may be interchanged with the direction orthogonal or substantially orthogonal to the longitudinal direction of the electrodes 3 and 4 illustrated in FIGS. 13A and 13B. That is, the electrode 3 and the electrode 4 may extend in a direction in which the first busbar 5 and the second busbar 6 extend in FIGS. 13A and 13B. In that case, the first busbar 5 and the second busbar 6 extend in a direction in which the electrode 3 and the electrode 4 extend in FIGS. 13A and 13B. A plurality of pairs of mutually adjacent electrodes, each pair including the electrode 3 connected with one potential and the electrode 4 connected with the other potential, are disposed in the direction orthogonal or substantially orthogonal to the longitudinal direction of the electrodes 3 and 4. When it is stated herein that the electrode 3 and the electrode 4 are adjacent to each other, this does not mean that the electrode 3 and the electrode 4 are disposed in direct contact with each other, but means that the electrode 3 and the electrode 4 are disposed with a spacing therebetween. Further, if the electrode 3 and the electrode 4 are adjacent to each other, no electrode connected with a hot electrode or a ground electrode, such as another electrode 3 or 4, is present between the mutually adjacent electrodes 3 and 4. The number of such electrode pairs does not need to be an integer but may be a non-integer such as, for example, 1.5 or 2.5. The center-to-center distance, that is, the pitch between the electrodes 3 and 4 is, for example, preferably greater than or equal to about 1 μm and less than or equal to about 10 μm. The width of each of the electrodes 3 and 4, that is, the dimension of each of the electrodes 3 and 4 in a direction in which the electrodes 3 and 4 face each other is, for example, preferably within the range of greater than or equal to about 50 nm and less than or equal to about 1000 nm, or more preferably within the range of greater than or equal to about 150 nm and less than or equal to about 1000 nm. The center-to-center distance between the electrodes 3 and 4 refers to the distance between the center of the dimension (width dimension) of the electrode 3 in the direction orthogonal or substantially orthogonal to the longitudinal direction of the electrode 3, and the center of the dimension (width dimension) of the electrode 4 in the direction orthogonal or substantially orthogonal to the longitudinal direction of the electrode 4.

Since the acoustic wave device 1 includes a Z-cut piezoelectric layer, the direction orthogonal or substantially orthogonal to the longitudinal direction of the electrodes 3 and 4 is a direction orthogonal or substantially orthogonal to the polarization direction of the piezoelectric layer 2. This, however, does not hold if a piezoelectric body with another cut-angle is used as the piezoelectric layer 2. As used herein, the term “orthogonal” may encompass not only strictly orthogonal but also substantially orthogonal (i.e., when the direction orthogonal to the longitudinal direction of the electrodes 3 and 4, and the polarization direction make an angle within the range of, for example, about 90°±10°).

A support 8 is stacked near the second major surface 2b of the piezoelectric layer 2 with an insulating layer 7 interposed therebetween. The insulating layer 7 and the support 8 have a frame shape, and respectively include a through-hole 7a and a through-hole 8a as illustrated in FIG. 14. Due to this configuration, a cavity 9 is provided. The cavity 9 is provided so that vibration of the excitation region C of the piezoelectric layer 2 is not prevented. Accordingly, the support 8 is stacked at the second major surface 2b with the insulating layer 7 interposed therebetween, such that the support 8 is positioned so as not to overlap the area where at least one pair of electrodes 3 and 4 are provided. No insulating layer 7 may be provided. Accordingly, the support 8 may be stacked directly or indirectly at the second major surface 2b of the piezoelectric layer 2.

The insulating layer 7 is made of, for example, silicon oxide. The insulating layer 7 may, however, be made of any suitable insulating material other than silicon oxide, such as, for example, silicon oxynitride or alumina. The support 8 is made of, for example, Si. The plane orientation of a face of Si near the piezoelectric layer 2 may be (100) or (110), or may be (111). Preferably, for example, Si of the support 8 has a high resistivity greater than or equal to about 4 kΩ cm. However, the support 8 may be made of any suitable insulative material or semiconductor material.

Examples of suitable materials of the support 8 may include piezoelectrics such as aluminum oxide, lithium tantalate, lithium niobate, or quartz, various ceramics such as alumina, magnesia, sapphire, silicon nitride, aluminum nitride, silicon carbide, zirconia, cordierite, mullite, steatite, or forsterite, dielectrics such as diamond or glass, and semiconductors such as gallium nitride.

The electrodes 3 and 4, and the first and second busbars 5 and 6 are each made of any suitable metal or alloy such as, for example, Al or AlCu alloy. In the acoustic wave device 1, the electrodes 3 and 4, and the first and second busbars 5 and 6 each include an Al film over a Ti film. However, an adhesion layer other than a Ti film may be used.

In driving, an alternating-current voltage is applied between the electrodes 3 and the electrodes 4. More specifically, an alternating-current voltage is applied between the first busbar 5 and the second busbar 6. This makes it possible to provide resonance characteristics utilizing bulk waves in thickness shear mode excited in the piezoelectric layer 2. The acoustic wave device 1 is designed such that d/p is, for example, less than or equal to about 0.5, where d is the thickness of the piezoelectric layer 2, and p is the center-to-center distance between any mutually adjacent electrodes 3 and 4 of a plurality of pairs of electrodes 3 and 4. This makes it possible to effectively excite the bulk waves in thickness shear mode mentioned above, and consequently provide improved resonance characteristics. More preferably, for example, d/p is less than or equal to about 0.24, in which case further improved resonance characteristics can be provided.

The above-described configuration of the acoustic wave device 1 makes it possible to reduce or prevent a decrease in Q-factor, even if the number of pairs of electrodes 3 and 4 is reduced to achieve miniaturization. This is because insertion loss is small even if the number of electrode fingers in a reflector at each side is reduced. The reason why the number of electrode fingers can be reduced as described above is because bulk waves in thickness shear mode are utilized. The difference between Lamb waves utilized in the acoustic wave device, and the bulk waves in thickness shear mode mentioned above is now described below with reference to FIG. 15A and FIG. 15B.

FIG. 15A is a schematic elevational cross-sectional view of a piezoelectric film of an acoustic wave device such as one described in Japanese Unexamined Patent Application Publication No. 2012-257019, illustrating Lamb waves propagating in the piezoelectric film. In the illustrated example, the waves propagate within a piezoelectric film 201 as indicated by arrows. In the present example, the piezoelectric film 201 includes a first major surface 201a, and a second major surface 201b that are positioned opposite from each other. The thickness direction connecting the first major surface 201a and the second major surface 201b is defined as the Z-direction. The X-direction refers to a direction in which the electrode fingers of the IDT electrode are arranged. As illustrated in FIG. 15A, Lamb waves propagate in the X-direction in the illustrated manner. Although the piezoelectric film 201 vibrates as a whole due to the Lamb waves being plate waves, since the waves propagate in the X-direction, a reflector is disposed at each side to provide resonance characteristics. This leads to wave propagation loss. Therefore, an attempt for miniaturization, that is, a reduction in the number of pairs of electrode fingers leads to a decrease in Q-factor.

In contrast, with the acoustic wave device 1, vibration displacement occurs in the thickness shear direction as illustrated in FIG. 15B. This results in the waves propagating substantially in the direction connecting the first major surface 2a and the second major surface 2b of the piezoelectric layer 2, that is, in the Z-direction, to achieve resonance. That is, the waves have an extremely small X-direction component relative to their Z-direction component. Since the wave propagation in the Z-direction provides the resonance characteristics, insertion loss is unlikely to occur even if the number of electrode fingers in the reflector is reduced. Further, a decrease in Q-factor is unlikely to occur, even if the number of pairs of electrodes 3 and 4 is reduced in an attempt to achieve further miniaturization.

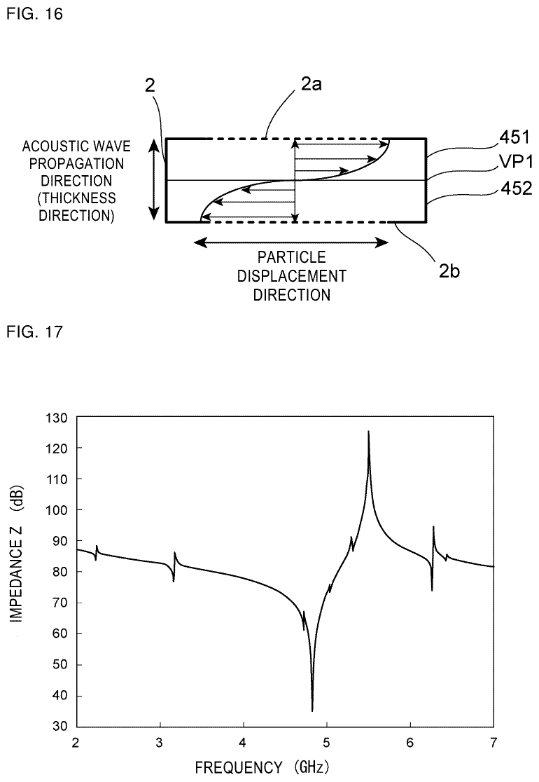

As illustrated in FIG. 16, the amplitude direction of bulk waves in thickness shear mode is opposite between a first region 451 and a second region 452, which are included in the excitation region C of the piezoelectric layer 2. FIG. 16 schematically illustrates bulk waves generated upon application of a voltage between the electrode 3 and the electrode 4 such that the electrode 4 is at a higher potential than the electrode 3. The first region 451 is a portion of the excitation region C located between a virtual plane VP1 and the first major surface 2a. The virtual plane VP1 is a plane that is orthogonal or substantially orthogonal to the thickness direction of the piezoelectric layer 2, and that divides the piezoelectric layer 2 into two regions. The second region 452 is a portion of the excitation region C located between the virtual plane VP1 and the second major surface 2b.

As described above, the acoustic wave device 1 includes at least one pair of electrodes including the electrodes 3 and 4. Since the acoustic wave device 1 is not designed for wave propagation in the X-direction, the acoustic wave device 1 does not necessarily need to include a plurality of such electrode pairs each including the electrode 3 and the electrode 4. That is, the acoustic wave device 1 may simply include at least one pair of electrodes.

For example, the electrode 3 is to be connected with a hot potential, and the electrode 4 is to be connected with a ground potential. Alternatively, however, the electrode 3 may be connected with a ground potential, and the electrode 4 may be connected with a hot potential. In the acoustic wave device 1, as described above, each of at least one pair of electrodes is an electrode to be connected with a hot potential or an electrode to be connected with a ground potential, and no floating electrode is provided.

FIG. 17 illustrates an example of the resonance characteristics of the acoustic wave device illustrated in FIG. 14. The acoustic wave device 1 provided with the resonance characteristics has design parameters described below.
Piezoelectric layer 2: LiNbO₃ having Euler angles (0°, 0°, 90°), with a thickness=about 400 nm.

The length of the region where the electrodes 3 and 4 overlap as seen in a direction orthogonal to the longitudinal direction of the electrodes 3 and 4, that is, the length of the excitation region C=about 40 μm, the number of electrode pairs each including electrodes 3 and 4=21, the center-to-center distance between electrodes=about 3 μm, the width of electrodes 3 and 4=about 500 nm, and d/p=about 0.133.
Insulating layer 7: silicon oxide film with a thickness of about 1 μm.
Support 8: Si.

The length of the excitation region C refers to a dimension of the excitation region C in the longitudinal direction of the electrodes 3 and 4.

In the acoustic wave device 1, the electrode-to-electrode distance is set equal or substantially equal between all electrode pairs each including the electrodes 3 and 4. That is, the electrodes 3 and 4 are disposed at equal or substantially equal pitches.

As can be appreciated from FIG. 17, improved resonance characteristics with a fractional bandwidth of about 12.5% are obtained, even though no reflector is provided.

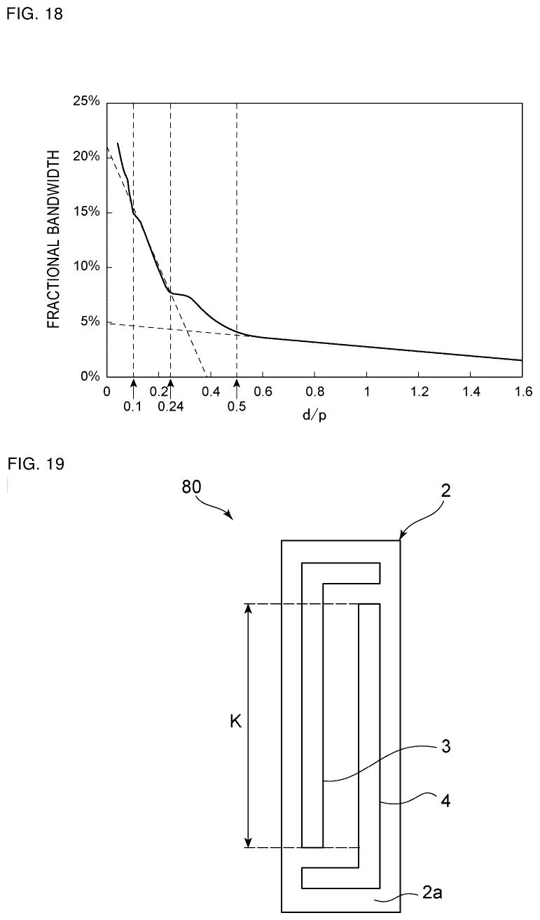

As previously described, in the acoustic wave device 1, d/p is, for example, less than or equal to about 0.5, or more preferably less than or equal to about 0.24, where d is the thickness of the piezoelectric layer 2, and p is the center-to-center distance between the electrode 3 and the electrode 4. This is explained below with reference to FIG. 18.

A plurality of acoustic wave devices are obtained in the same or substantially the same manner as with the acoustic wave device having the resonance characteristics illustrated in FIG. 17, but with varying values of d/p. FIG. 18 illustrates the relationship between d/p, and the fractional bandwidth of the acoustic wave device defining and functioning as a resonator.

As is apparent from FIG. 18, when d/p>about 0.5, the fractional bandwidth remains below about 5% even as d/p is adjusted. In contrast, when d/p≤about 0.5, varying d/p within this range makes it possible to provide a fractional bandwidth of greater than or equal to about 5%, that is, a resonator with a high coupling coefficient. When d/p is less than or equal to about 0.24, the fractional bandwidth can be increased to be greater than or equal to about 7%. In addition, adjusting d/p within this range makes it possible to provide a resonator with an even greater fractional bandwidth, and consequently with an even higher coupling coefficient. It can therefore be appreciated that setting d/p less than or equal to about 0.5 makes it possible to provide a resonator that utilizes the bulk waves in thickness shear mode mentioned above and that has a high coupling coefficient.

FIG. 19 is a plan view of an acoustic wave device that utilizes bulk waves in thickness shear mode. An acoustic wave device 80 includes one electrode pair including the electrodes 3 and 4 provided on the first major surface 2a of the piezoelectric layer 2. In FIG. 19, K represents intersecting width. As previously described, an acoustic wave device according to an example embodiment of the present invention may include a single pair of electrodes. In this case as well, bulk waves in thickness shear mode can be effectively excited if the ratio d/p mentioned above is less than or equal to about 0.5, for example.

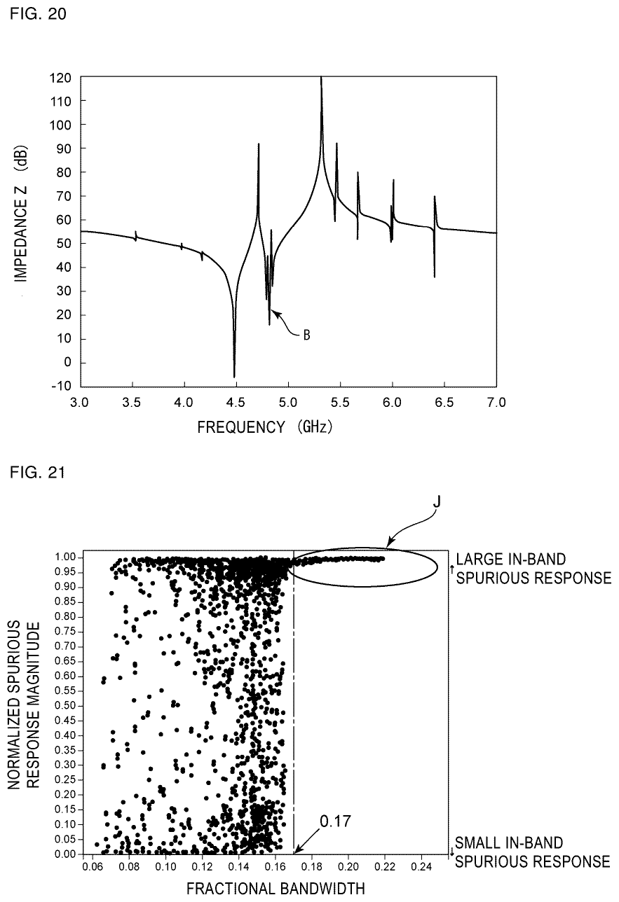

In a preferred configuration of the acoustic wave device 1, for example, the following condition is satisfied: MR about 1.75(d/p)+0.075, where MR is the metallization ratio of any mutually adjacent electrodes 3 and 4 of a plurality of electrodes 3 and 4 to the excitation region C, which is a region where the mutually adjacent electrodes 3 and 4 overlap as seen in a direction in which the mutually adjacent electrodes 3 and 4 face each other. This configuration allows for effective reduction of a spurious response. This is explained below with reference to FIGS. 20 and 21. FIG. 20 illustrates, for reference, an example of the resonance characteristics of the acoustic wave device 1. A spurious response indicated by an arrow B appears between the resonant frequency and the anti-resonant frequency. It is to be noted that d/p is set as d/p=about 0.08, and the Euler Angles of LiNbO₃ are set as (0°, 0°, 90°). The metallization ratio MR mentioned above is set as MR=about 0.35.

The metallization ratio MR is described below with reference to FIG. 13B. With attention directed to one pair of electrodes 3 and 4 in the arrangement of electrodes illustrated in FIG. 13B, it is now assumed that only the one pair of electrodes 3 and 4 exists. In this case, the portion bounded by a dash-dot line is the excitation region C. As seen in a direction orthogonal or substantially orthogonal to the longitudinal direction of the electrodes 3 and 4, that is, in a direction in which the electrodes 3 and 4 face each other, the excitation region C includes the following regions: a region of the electrode 3 that overlaps the electrode 4; a region of the electrode 4 that overlaps the electrode 3; and the region located between the electrodes 3 and 4 and where the electrodes 3 and 4 overlap each other. In this case, the metallization ratio MR refers to the ratio of the area of the electrodes 3 and 4 within the excitation region C to the area of the excitation region C. That is, the metallization ratio MR refers to the ratio of the area of the metallization part to the area of the excitation region C.

For a case where a plurality of pairs of electrodes are provided, the metallization ratio MR may be defined as a proportion, relative to the sum of the areas of excitation regions, of the metallization portions included in all of the excitation regions.

FIG. 21 illustrates, for a case where a large number of surface acoustic wave resonators are provided in accordance with the configuration of the acoustic wave device 1, the relationship between fractional bandwidth, and the magnitude of the spurious response, which is represented by the phase rotation of the spurious impedance normalized to about 180 degrees. The fractional bandwidth is adjusted by varying, for example, the film thickness of the piezoelectric layer and the dimensions of individual electrodes. Although FIG. 21 illustrates the results for a case where a piezoelectric layer made of, for example, Z-cut LiNbO₃ is used, a similar tendency is observed as well for cases where a piezoelectric layer with another cut-angle is used.

The region bounded by an ellipse J in FIG. 21 exhibits a large spurious response of about 1.0. As appreciated from FIG. 21, at fractional bandwidths above about 0.17, that is, above about 17%, a large spurious response with a spurious level of about 1 or greater appears within the pass band even if parameters constituting the fractional bandwidth are varied. That is, as with the resonance characteristics illustrated in FIG. 20, a large spurious response indicated by the arrow B appears within the band. Thus, the fractional bandwidth is, for example, preferably less than or equal to about 17%. In this case, the spurious response can be reduced by adjusting, for example, the film thickness of the piezoelectric layer 2 or the respective dimensions of the electrodes 3 and 4.

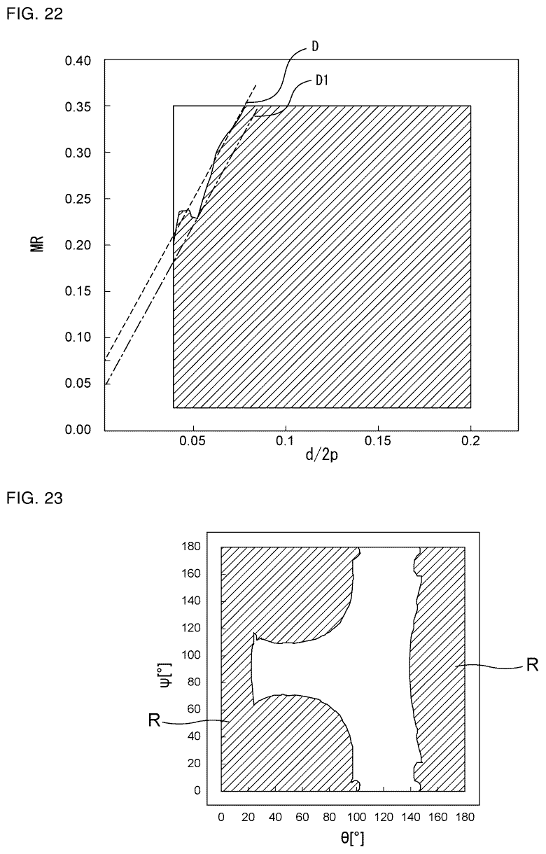

FIG. 22 illustrates the relationship between d/2p, metallization ratio MR, and fractional bandwidth. As the acoustic wave device described above, acoustic wave devices with different values of d/2p and MR are provided, and their fractional bandwidths are measured. The hatched region on the right-hand side of a broken line D in FIG. 22 represents a region with a fractional bandwidth of less than or equal to about 17%. The boundary between the hatched region and the non-hatched region is represented as MR=about 3.5(d/2p)+0.075. That is, MR=about 1.75(d/p)+0.075. Accordingly, for example, it is preferable that MR about 1.75(d/p)+0.075. In that case, a fractional bandwidth of less than or equal to about 17% can be easily obtained. A more preferable example of the above-described region is the region on the right-hand side of a dash-dot line D1 in FIG. 22 that represents MR=about 3.5(d/2p)+0.05. In other words, if MR≤about 1.75(d/p)+0.05, this makes it possible to reliably achieve a fractional bandwidth of less than or equal to about 17%.

FIG. 23 illustrates a map of fractional bandwidth with respect to the Euler angles (0°, θ, ψ) of LiNbO₃ with d/p set as close to zero as possible. A plurality of hatched regions R in FIG. 23 each represent a region where a fractional bandwidth of greater than or equal to about 2% is obtained. For a case where φ of the Euler Angles (φ, θ, ψ) is within the range of about 0°±5°, the relationship between fractional bandwidth, and each of θ and ψ is the same or substantially the same as the relationship illustrated in FIG. 23. For a case where the piezoelectric layer is made of, for example, lithium tantalate (LiTaO₃) as well, the relationship between BW, and each of θ and ψ of the Euler Angles (0°±5°, θ, ψ) is the same substantially the same as the relationship illustrated in FIG. 23.

Accordingly, if φ of the Euler Angles (φ, θ, ψ) of lithium niobate or lithium tantalate that constitutes the piezoelectric layer is within the range of about 0°±5°, and θ and φ fall within any of the regions R illustrated in FIG. 23, such a configuration is preferred for its ability to provide a sufficiently large fractional bandwidth.

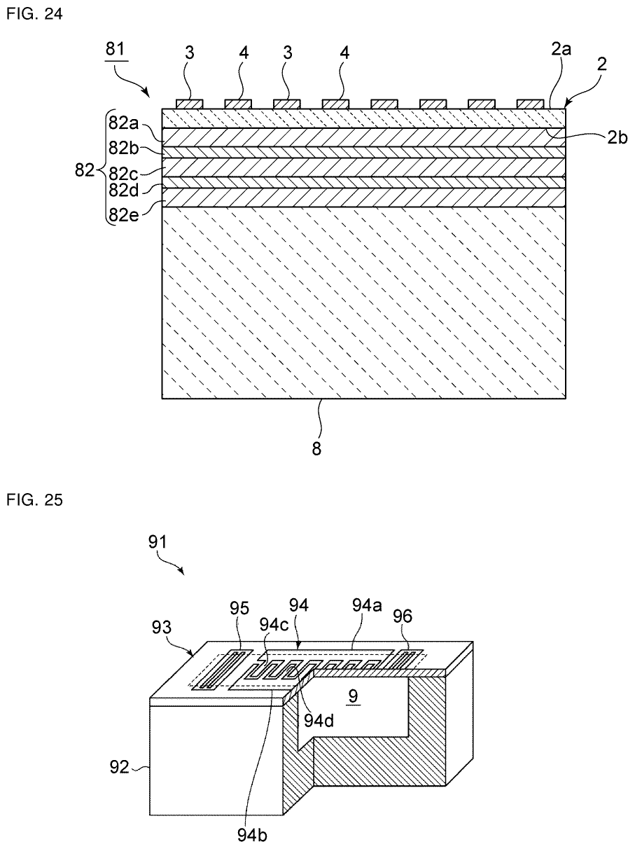

FIG. 24 is an elevational cross-sectional view of an acoustic wave device including an acoustic multilayer film.

In an acoustic wave device 81, an acoustic multilayer film 82 is stacked on the second major surface 2b of the piezoelectric layer 2. The acoustic multilayer film 82 has a multilayer structure including low acoustic impedance layers 82a, 82c, and 82e each having relatively low acoustic impedance, and high acoustic impedance layers 82b and 82d each having relatively high acoustic impedance. Use of the acoustic multilayer film 82 allows bulk waves in thickness shear mode to be confined within the piezoelectric layer 2, even without use of the cavity 9 provided in the acoustic wave device 1. With the acoustic wave device 81 as well, for example, setting the ratio d/p mentioned above to less than or equal to about 0.5 makes it possible to provide resonance characteristics based on bulk waves in thickness shear mode. However, in the acoustic multilayer film 82, the number of low acoustic impedance layers 82a, 82c, 82e to be stacked, and the number of high acoustic impedance layers 82b, 82d to be stacked are not particularly limited. It may suffice that at least one high acoustic impedance layer 82b, 82d is positioned farther from the piezoelectric layer 2 relative to the low acoustic impedance layer 82a, 82c, 82e.

The low acoustic impedance layers 82a, 82c, and 82e, and the high acoustic impedance layers 82b and 82d may each be made of any suitable material as long as the above-described relationship between their acoustic impedances is satisfied. Examples of suitable materials for the low acoustic impedance layers 82a, 82c, and 82e may include silicon oxide and silicon oxynitride. Examples of suitable materials for the high acoustic impedance layers 82b and 82d may include alumina, silicon nitride, and metal.

FIG. 25 is a partially cutaway perspective view of an acoustic wave device that utilizes Lamb waves.

An acoustic wave device 91 includes a support substrate 92. The support substrate 92 includes a recess that opens at the top. A piezoelectric layer 93 is disposed on the support substrate 92. Due to the configuration described above, the cavity 9 is provided. An IDT electrode 94 is disposed above the cavity 9 and on the piezoelectric layer 93. Reflectors 95 and 96 are disposed at opposite sides of the IDT electrode 94 in the direction of acoustic wave propagation. In FIG. 25, the peripheral edges of the cavity 9 are represented by broken lines. In this case, the IDT electrode 94 includes first and second busbars 94a and 94b, a plurality of first electrode fingers 94c, and a plurality of second electrode fingers 94d. The first electrode fingers 94c are connected to the first busbar 94a. The second electrode fingers 94d are connected to the second busbar 94b. The first electrode fingers 94c, and the second electrode fingers 94d are interdigitated with each other.

In the acoustic wave device 91, Lamb waves, which are plate waves, are excited through application of an alternating-current electric field to the IDT electrode 94 disposed over the cavity 9. The presence of the reflectors 95 and 96 at opposite sides makes it possible to provide resonance characteristics due to the Lamb waves.

As described above, an acoustic wave device according to an example embodiment of the present invention may utilize plate waves. In the example illustrated in FIG. 25, the IDT electrode 94, the reflector 95, and the reflector 96 are disposed on a major surface corresponding to the first major surface 14a of the piezoelectric layer 14 illustrated in FIG. 1 or other figures. In the present example embodiment, the pair of comb-shaped electrodes are disposed on the first major surface 14a, and the third electrode fingers are disposed on the first major surface 14a or the second major surface 14b. If the acoustic wave device according to the present example embodiment is one that utilizes plate waves, it may suffice that the reflector 95 and the reflector 96 are disposed on the first major surface 14a of the piezoelectric layer 14 according to each of the first example embodiment, the second example embodiment, and the modification. In this case, it may suffice that in plan view, the reflector 95 and the reflector 96 are positioned with the pair of comb-shaped electrodes and the third electrode fingers being interposed therebetween in the orthogonal-to-electrode-finger direction.

In each of the acoustic wave devices according to the first example embodiment, the second example embodiment, and the modification, for example, the acoustic multilayer film 82 illustrated in FIG. 24, which defines and functions as an acoustic reflection film, may be disposed between the support, and the piezoelectric layer defining and functioning as a piezoelectric film. Specifically, the support and the piezoelectric film may be positioned such that at least a portion of the support and at least a portion of the piezoelectric film face each other across the acoustic multilayer film 82. In this case, in the acoustic multilayer film 82, a low acoustic impedance layer and a high acoustic impedance layer may be stacked alternately. The acoustic multilayer film 82 may define and function as an acoustic reflection part of the acoustic wave device.

In each of the acoustic wave devices according to the first example embodiment, the second example embodiment, and the modification that utilize bulk waves in thickness shear mode, as described above, d/p is, for example, preferably less than or equal to about 0.5, or more preferably less than or equal to about 0.24. This configuration allows for further improved resonance characteristics.

Further, for example, it is preferable that in the excitation region of each of the acoustic wave devices according to the first example embodiment, the second example embodiment, and the modification that utilize bulk waves in thickness shear mode, the condition MR about 1.75(d/p)+0.075 be satisfied. More specifically, when the metallization ratio of one of the first, second, and third electrode fingers excluding consecutive electrode fingers to the excitation region, and the metallization ratio of each of the consecutive electrode fingers to the excitation region are each denoted MR, the metallization ratio MR preferably satisfies the condition MR about 1.75(d/p)+0.075, for example. This configuration enables further reliable reduction of spurious response.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric film including a piezoelectric layer;
a first comb-shaped electrode on the piezoelectric layer and connected to an input potential, the first comb-shaped electrode including:
a first busbar; and
a plurality of first electrode fingers each connected at one end to the first busbar;
a second comb-shaped electrode on the piezoelectric layer and connected to an output potential, the second comb-shaped electrode including:
a second busbar; and
a plurality of second electrode fingers each connected at one end to the second busbar, and being interdigitated with the first electrode fingers; and
a third electrode connected to a potential different from the first comb-shaped electrode and the second comb-shaped electrode, the third electrode including:
a plurality of third electrode fingers each being provided on the piezoelectric layer such that, as seen in plan view, the plurality of third electrode fingers are arranged alongside the plurality of first electrode fingers and the plurality of second electrode fingers in a direction in which the first electrode finger and the second electrode finger are arranged; and
a third busbar interconnecting adjacent third electrode fingers; wherein
one of the plurality of third electrode fingers is located between first and second electrode fingers located nearest each other; and
when a direction orthogonal or substantially orthogonal to a direction in which the plurality of first electrode fingers, the plurality of second electrode fingers, and the plurality of third electrode fingers extend is defined as an orthogonal-to-electrode-finger direction, at least one plurality of electrode fingers selected from the plurality of first electrode fingers, the plurality of second electrode fingers, and the plurality of third electrode fingers include two or more consecutive electrode fingers provided consecutively in the orthogonal-to-electrode-finger direction.

2. The acoustic wave device according to claim 1, wherein the plurality of third electrode fingers include the two or more consecutive electrode fingers.

3. The acoustic wave device according to claim 1, wherein g2≤g1, where g1 is a distance between an electrode finger and one of the consecutive electrode fingers, the electrode finger being one of the plurality of first, second, and third electrode fingers adjacent to the one of the consecutive electrode fingers and connected to a potential different from the one of the consecutive electrode fingers, and g2 is a distance between the consecutive electrode fingers that are adjacent to each other.

4. The acoustic wave device according to claim 1, wherein the acoustic wave device is configured to excite a bulk wave in thickness shear mode.

5. The acoustic wave device according to claim 1, further comprising:
a support stacked on the piezoelectric film; wherein
as seen in plan view in a direction in which the support and the piezoelectric film are stacked, an acoustic reflection portion is provided in a location at the support where the acoustic reflection portion overlaps the plurality of first electrode fingers, the plurality of second electrode fingers, and the plurality of third electrode fingers; and
when the two or more consecutive electrode fingers provided consecutively in the orthogonal-to-electrode-finger direction are defined as a set of the consecutive electrode fingers, a ratio d/p is less than or equal to about 0.5, where d is a thickness of the piezoelectric film, p is a distance between a center of an electrode finger in the orthogonal-to-electrode-finger direction and a center of the set of the consecutive electrode fingers in the orthogonal-to-electrode-finger direction, the electrode finger being one of the plurality of first, second, and third electrode fingers adjacent to the set of the consecutive electrode fingers and connected to a potential different from the set of the consecutive electrode fingers.

6. The acoustic wave device according to claim 5, wherein the ratio d/p is less than or equal to about 0.24.

7. The acoustic wave device according to claim 5, wherein the acoustic reflection portion is a cavity, and the support and the piezoelectric film are positioned such that a portion of the support and a portion of the piezoelectric film face each other across the cavity.

8. The acoustic wave device according to claim 5, wherein
the acoustic reflection portion is an acoustic reflection film including:
a high acoustic impedance layer with a relatively high acoustic impedance; and
a low acoustic impedance layer with a relatively low acoustic impedance; and
the support and the piezoelectric film are positioned such that at least a portion of the support and at least a portion of the piezoelectric film face each other across the acoustic reflection film.

9. The acoustic wave device according to claim 5, wherein
an excitation region is located between a center of an electrode finger in the orthogonal-to-electrode-finger direction and a center of the set of the consecutive electrode fingers in the orthogonal-to-electrode-finger direction, the electrode finger being one of the plurality of first, second, and third electrode fingers adjacent to the set of the consecutive electrode fingers and connected to a potential different from the set of the consecutive electrode fingers; and
when a metallization ratio of an electrode finger to the excitation region, and a metallization ratio of each of the consecutive electrode fingers to the excitation region are each denoted MR, the metallization ratio MR satisfies a condition MR≤about 1.75(d/p)+0.075, the electrode finger being one of the plurality of first, second, and third electrode fingers excluding the consecutive electrode fingers.

10. The acoustic wave device according to claim 1, wherein
the piezoelectric layer includes lithium niobate; and
the lithium niobate of the piezoelectric layer has Euler Angles (φ, θ, ψ) within a range represented by Expression (1), Expression (2), or Expression (3):
(0°±10°,0° to 25°, any ψ) (1);
(0°±10°,25° to 100°,0° to 75° [(1−(θ−50)²/2500)]^{1/2} or 180°−75°[(1−(θ−50)²/2500)]^{1/2} to 180°) (2); and
(0°±10°,180°−40° [(1−(ψ−90)²/8100)]^{1/2} to 180°, any ψ) (3).

11. The acoustic wave device according to claim 1, wherein the potential to which the third electrode is connected is a ground potential.

12. The acoustic wave device according to claim 1, wherein an insulating film is provided between the third busbar and each of the plurality of first electrode fingers.

13. The acoustic wave device according to claim 5, wherein
the support includes a support substrate and an insulating layer on the support substrate; and
the piezoelectric film is on the insulating layer.

14. The acoustic wave device according to claim 13, wherein the support substrate includes silicon or aluminum oxide.

15. The acoustic wave device according to claim 13, wherein the insulating layer includes silicon oxide or tantalum oxide.

16. The acoustic wave device according to claim 1, wherein each of the plurality of first, second, and third electrode fingers includes aluminum.

17. The acoustic wave device according to claim 13, wherein
the insulating layer includes a recess; and
the piezoelectric layer covers the recess.

18. The acoustic wave device according to claim 1, wherein each of the plurality of first, second, and third electrode fingers includes aluminum.
